(19) United States
(12) Patent Application Publication
(10) Pub. No.: US 2026/0140161 A1
(43) Pub. Date: May 21, 2026

(54) Device For Insulation Detection And Method For The Same

(71) Applicant: VERTIV CORPORATION, Westerville, OH (US)

(72) Inventors: Zhongchang SUN, Shenzhen (CN); Renliang WANG, Shenzhen (CN)

(73) Assignee: VERTIV CORPORATION, Westerville, OH (US)

(21) Appl. No.: 19/228,438

(22) Filed: Jun. 4, 2025

(30) Foreign Application Priority Data
Nov. 18, 2024 (CN) 202411650997.5

(51) Int. Cl. G01R 31/14

(52) U.S. Cl. CPC G01R 31/14

(57) ABSTRACT

Devices and methods for insulation detection are provided. The device includes a voltage acquisition unit, a calculation unit and at least two resistance units. Each resistance unit is electrically connected to a ground terminal and a target output wire. The voltage acquisition unit acquires a positive bus-to-ground voltage, a negative bus-to-ground voltage and a neutral-to-ground voltage after a target resistance unit connects a path between target output wire and ground terminal. The calculation unit calculates first current corresponding to target output wire based on voltage corresponding to the target output wire and the resistance of the target resistance unit; calculates a positive insulation resistance to ground, a negative insulation resistance to ground and a neutral-wire insulation resistance to ground based on first current, positive bus-to-ground voltage, negative bus-to-ground voltage and neutral-to-ground voltage; and determines whether insulation failure occurs in three-wire HVDC system.

### CROSS-REFERENCE TO RELATED APPLICATION

This application claims priority to Chinese Patent Application No. 202411650997.5, filed on Nov. 18, 2024, entitled “DEVICE FOR INSULATION DETECTION AND METHOD FOR THE SAME”, the disclosure of which is incorporated herein by reference in its entirety.

### FIELD

The present disclosure relates to the technical field of insulation detection, and in particular to a device and a method for insulation detection.

### BACKGROUND

With the development of power systems, High-Voltage Direct Current (HVDC) transmission technology has become a preferred solution for long-distance, high-power electricity transmission. In a three-wire HVDC system, a positive bus, a negative bus and a neutral wire are typically included to improve transmission efficiency and system stability. However, the safety and reliability of the system largely depend on its insulation performance. An insulation failure may lead to power transmission interruptions, device damage and even safety accidents.

In the prior art, a device for insulation detection is mainly used for two-wire HVDC systems. Insulation detection for three-wire HVDC systems is an urgent problem that those skilled in the art need to resolve.

### SUMMARY

The present disclosure provides a device and a method for insulation detection, to implement insulation detection for three-wire HVDC systems.

In a first aspect, an embodiment of the present disclosure provides a device for insulation detection which is applied to a three-wire HVDC system and includes a voltage acquisition unit, a calculation unit and at least two resistance units.

Each of the resistance units is electrically connected to a ground terminal and a target output wire of the three-wire HVDC system, where the target output wire includes at least one of a positive bus, a negative bus and a neutral wire;

The voltage acquisition unit is configured to acquire a positive bus-to-ground voltage, a negative bus-to-ground voltage and a neutral-to-ground voltage after a target resistance unit connects a path between the target output wire and the ground terminal.

The calculation unit is electrically connected to the voltage acquisition unit and is configured to: calculate a first current corresponding to the target output wire based on a voltage corresponding to the target output wire and a resistance of the target resistance unit; calculate a positive insulation resistance to ground, a negative insulation resistance to ground and a neutral-wire insulation resistance to ground based on the first current, the positive bus-to-ground voltage, the negative bus-to-ground voltage and the neutral-to-ground voltage; and determine whether an insulation failure occurs in the three-wire HVDC system based on the positive insulation resistance to ground, the negative insulation resistance to ground and the neutral-wire insulation resistance to ground.

In a possible implementation, the target output wire includes one of the positive bus, the negative bus and the neutral wire.

Each of the resistance units includes a first switch and a first resistance subunit, where the first resistance subunit includes at least one first resistor.

A first terminal of the first resistance subunit is electrically connected to the target output wire, and a second terminal of the first resistance subunit is electrically connected to a first terminal of the first switch.

A second terminal of the first switch is electrically connected to the ground terminal.

In a possible implementation, the target output wire includes a first target output wire and a second target output wire, where the first target output wire and the second target output wire are any two of the positive bus, the negative bus and the neutral wire and the first target output wire is different from the second target output wire.

Each of the resistance units includes a second switch, a second resistance subunit and a third resistance subunit, where the second resistance subunit includes at least one second resistor, and the third resistance subunit includes at least one third resistor.

A first terminal of the second resistance subunit is electrically connected to the first target output wire, and a second terminal of the second resistance subunit is electrically connected to a first terminal of the second switch.

A first terminal of the third resistance subunit is electrically connected to the second target output wire, and a second terminal of the third resistance subunit is electrically connected to the first terminal of the second switch.

A second terminal of the second switch is electrically connected to the ground terminal.

In a possible implementation, the target output wire includes the positive bus, the negative bus and the neutral wire.

Each of the resistance units includes a third switch, a fourth resistance subunit, a fifth resistance subunit and a sixth resistance subunit, where the fourth resistance subunit includes at least one fourth resistor, the fifth resistance subunit includes at least one fifth resistor, and the sixth resistance subunit includes at least one sixth resistor.

A first terminal of the fourth resistance subunit is electrically connected to the negative bus of the target output wire, and a second terminal of the fourth resistance subunit is electrically connected to a first terminal of the third switch.

A first terminal of the fifth resistance subunit is electrically connected to the neutral wire of the target output wire, and a second terminal of the fifth resistance subunit is electrically connected to the first terminal of the third switch.

A first terminal of the sixth resistance subunit is electrically connected to the positive bus of the target output wire, and a second terminal of the sixth resistance subunit is electrically connected to the first terminal of the third switch.

A second terminal of the third switch is electrically connected to the ground terminal.

In a possible implementation, the device for insulation detection further includes a ground resistance unit, where the ground resistance unit includes at least one ground resistor.

One terminal of the ground resistor is electrically connected to one output wire of the three-wire HVDC system, and the other terminal of the ground resistor is electrically connected to the ground terminal.

In a possible implementation, the calculation unit is configured to:
calculate a first quotient of the voltage corresponding to the target output wire and a resistance of the target resistance unit to acquire the first current;
generate the first current equation, the second current equation and the third current equation based on the first current, a positive bus current, a negative bus current and a neutral wire current, where the first current equation, the second current equation and the third current equation are generated based on different target resistance units; and
calculate the positive insulation resistance to ground, the negative insulation resistance to ground and the neutral-wire insulation resistance to ground based on the first current equation, the second current equation and the third current equation.

In a possible implementation, the calculation unit is further configured to:
calculate a second quotient of the voltage corresponding to the target output wire and a resistance of the ground resistance unit to acquire a second current corresponding to the target output wire;
generate a fourth current equation, a fifth current equation and a sixth current equation based on the first current, the second current, the positive bus current, the negative bus current and the neutral wire current; and
calculate the positive insulation resistance to ground, the negative insulation resistance to ground and the neutral-wire insulation resistance to ground based on the fourth current equation, the fifth current equation and the sixth current equation.

In a second aspect, an embodiment of the present disclosure provides a method for insulation detection which is applied to the device for insulation detection described in any one of the first aspect and includes:
acquiring the positive bus-to-ground voltage, the negative bus-to-ground voltage and the neutral-to-ground voltage after the target resistance unit connects the path between the target output wire and the ground terminal;
calculating the first current corresponding to the target output wire based on the voltage corresponding to the target output wire and the resistance of the target resistance unit;
calculating the positive insulation resistance to ground, the negative insulation resistance to ground and the neutral-wire insulation resistance to ground based on the first current, the positive bus-to-ground voltage, the negative bus-to-ground voltage and the neutral-to-ground voltage; and
determining whether an insulation failure occurs in the three-wire HVDC system based on the positive insulation resistance to ground, the negative insulation resistance to ground and the neutral-wire insulation resistance to ground.

In a possible implementation, the calculating the positive insulation resistance to ground, the negative insulation resistance to ground and the neutral-wire insulation resistance to ground based on the first current, the positive bus-to-ground voltage, the negative bus-to-ground voltage and the neutral-to-ground voltage includes:
calculating the first quotient of the voltage corresponding to the target output wire and the resistance of the target resistance unit as the first current;
generating the first current equation, the second current equation and the third current equation based on the first current, the positive bus current, the negative bus current and the neutral wire current, where the first current equation, the second current equation and the third current equation are generated based on different target resistance units; and
calculate the positive insulation resistance to ground, the negative insulation resistance to ground and the neutral-wire insulation resistance to ground based on the first current equation, the second current equation and the third current equation.

In a possible implementation, the method further includes:
calculating the second quotient of the voltage corresponding to the target output wire and a resistance of the ground resistance unit to acquire a second current;
generating a fourth current equation, a fifth current equation and a sixth current equation based on the first current, the second current, the positive bus current, the negative bus current and the neutral wire current; and
calculating the positive insulation resistance to ground, the negative insulation resistance to ground and the neutral-wire insulation resistance to ground based on the fourth current equation, the fifth current equation and the sixth current equation.

The beneficial effects of the present disclosure are as follows:

A device and a method for insulation detection are provided. The device for insulation detection includes the voltage acquisition unit, the calculation unit and at least two resistance units. Each of the resistance units is electrically connected to the ground terminal and the target output wire of the three-wire HVDC system. The voltage acquisition unit is configured to acquire the positive bus-to-ground voltage, the negative bus-to-ground voltage and the neutral-to-ground voltage after the target resistance unit connects the path between the target output wire and the ground terminal. The calculation unit is configured to calculate the first current corresponding to the target output wire based on the voltage corresponding to the target output wire and the resistance of the target resistance unit; calculate the positive insulation resistance to ground, the negative insulation resistance to ground and the neutral-wire insulation resistance to ground based on the first current, the positive bus-to-ground voltage, the negative bus-to-ground voltage and the neutral-to-ground voltage; and determine whether an insulation failure occurs in the three-wire HVDC system based on the positive insulation resistance to ground, the negative insulation resistance to ground and the neutral-wire insulation resistance to ground. The device for insulation detection according to embodiments of the present disclosure can perform insulation detection on the three-wire HVDC system, thereby improving safety and reliability of the three-wire HVDC system.

### BRIEF DESCRIPTION OF THE DRAWINGS

In order to more clearly describe technical solutions in embodiments of the present disclosure, the drawings to be used in the description of the embodiments are briefly described below. Apparently, the drawings described in the following description show only some embodiments of the present disclosure, and from the drawings, those skilled in the art can obtain other drawings without any creative effort.

FIG. 1 is a schematic structural diagram of a three-wire HVDC system using a related art;

FIG. 2 is a schematic structural diagram of a device for insulation detection according to an embodiment of the present disclosure;

FIG. 3 is a schematic diagram of an equivalent circuit of insulation resistance to ground according to an embodiment of the present disclosure;

FIG. 4 is a schematic diagram of a circuit of a resistance unit according to an embodiment of the present disclosure;

FIG. 5 is a schematic diagram of a circuit of another resistance unit according to an embodiment of the present disclosure;

FIG. 6 is a schematic diagram of a circuit of another resistance unit according to an embodiment of the present disclosure;

FIG. 7 is a schematic diagram of a circuit of another resistance unit according to an embodiment of the present disclosure;

FIG. 8 is a schematic structural diagram of another resistance unit according to an embodiment of the present disclosure;

FIG. 9 is a schematic diagram of a circuit of another resistance unit according to an embodiment of the present disclosure;

FIG. 10 is a schematic diagram of a circuit of another resistance unit according to an embodiment of the present disclosure;

FIG. 11 is a schematic structural diagram of another resistance unit according to an embodiment of the present disclosure;

FIG. 12 is a schematic diagram of a circuit of another resistance unit according to an embodiment of the present disclosure;

FIG. 13 is a schematic diagram of a circuit of another resistance unit according to an embodiment of the present disclosure;

FIG. 14 is a schematic structural diagram of a device for insulation detection according to an embodiment of the present disclosure;

FIG. 15 is a schematic diagram of a circuit of a device for insulation detection according to an embodiment of the present disclosure;

FIG. 16 is a schematic diagram of a circuit of another device for insulation detection according to an embodiment of the present disclosure; and

FIG. 17 is a schematic flowchart of a method for insulation detection according to an embodiment of the present disclosure.

### DETAILED DESCRIPTION

In order to make the object, technical solutions and advantages of the embodiments of the present disclosure clearer, the present disclosure is further described hereinafter in detail in combination with the drawings. Apparently, the described embodiments are only some embodiments of the present disclosure, rather than all embodiments. All of other embodiments obtained by those skilled in the art based on the embodiments described in the present disclosure without any creative work will fall within the protection scope of the present disclosure.

It should be noted that the terms “first”, “second”, and the like in the description, claims and the drawings of the present disclosure are used to distinguish similar objects, rather than to describe a specific order or sequence. It should be understood that the terms used in this way may be interchangeable where appropriate so that embodiments of the present disclosure described herein can be implemented in an order other than those illustrated or described herein. The embodiments described in the following exemplary embodiments do not represent all the embodiments consistent with the present disclosure. Rather, they are merely examples of devices and methods consistent with some aspects of the present disclosure as detailed in the claims as attached.

Reference is made to FIG. 1, which is a schematic structural diagram of a three-wire High-Voltage Direct Current (HVDC) system using a related art. The three-wire HVDC system includes an HVDC power supply unit, a positive bus A, a neutral wire B, and a negative bus C, where the neutral wire B may also be referred to as a ground return wire.

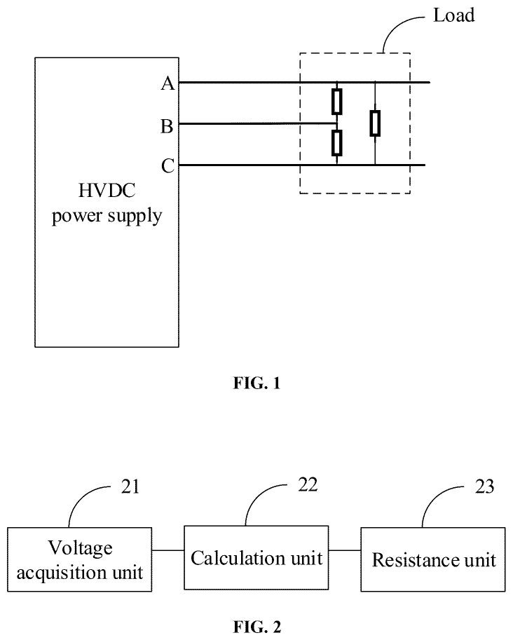

In order to implement insulation detection for the three-wire HVDC system, the embodiment of the present disclosure provides a device for insulation detection which is applied to the three-wire HVDC system shown in FIG. 1. Reference is made to FIG. 2, which is a schematic structural diagram of a device for insulation detection according to the embodiment of the present disclosure. The device for insulation detection includes a voltage acquisition unit 21, a calculation unit 22 and at least two resistance units 23;

Each resistance unit 23 is electrically connected to a ground terminal and a target output wire of the three-wire HVDC system, where the target output wire includes at least one of the positive bus, the negative bus and the neutral wire.

The voltage acquisition unit 21 is configured to acquire a positive bus-to-ground voltage U+, a negative bus-to-ground voltage U− and a neutral-to-ground voltage U0 after a target resistance unit connects a path between the target output wire and the ground terminal.

The calculation unit 22 is electrically connected to the voltage acquisition unit 21 and is configured to: calculate a first current I1 corresponding to the target output wire based on the voltage corresponding to the target output wire and a resistance of the target resistance unit; calculate a positive insulation resistance to ground Rₑ₊, a negative insulation resistance to ground Rₑ₋ and a neutral-wire insulation resistance to ground Rₑ₀ based on the first current I1, the positive bus-to-ground voltage U+, the negative bus-to-ground voltage U− and the neutral-to-ground voltage U0; and determine whether an insulation failure occurs in the three-wire HVDC system based on the positive insulation resistance to ground Rₑ₊, the negative insulation resistance to ground Rₑ₋ and the neutral-wire insulation resistance to ground Rₑ₀.

In the embodiment according to the present disclosure, each resistance unit 23 is electrically connected to the ground terminal and the target output wire of the three-wire HVDC system. The voltage acquisition unit 21 acquires the positive bus-to-ground voltage U+, the negative bus-to-ground voltage U− and the neutral-to-ground voltage U0 after the target resistance unit connects a path between the target output wire and the ground terminal. The calculation unit 22 calculates the first current I1 corresponding to the target output wire based on the voltage corresponding to the target output wire and the resistance of the target resistance unit; calculates the positive insulation resistance to ground Rₑ₊, the negative insulation resistance to ground Rₑ₋ and the neutral-wire insulation resistance to ground Rₑ₀ based on the first current I1, the positive bus-to-ground voltage U+, the negative bus-to-ground voltage U− and the neutral-to-ground voltage U0; and determines whether an insulation failure occurs in the three-wire HVDC system based on the positive insulation resistance to ground Rₑ₊, the negative insulation resistance to ground Rₑ₋ and the neutral-wire insulation resistance to ground Rₑ₀. The device for insulation detection according to the embodiment of the present disclosure can perform insulation detection on the three-wire HVDC system, thereby improving safety and reliability of the three-wire HVDC system.

Referring to FIG. 3, R+ represents a positive insulation resistor to ground, and a resistance of the positive insulation resistor to ground R+ is the positive insulation resistance to ground Rₑ₊. R− represents a negative insulation resistor to ground, and a resistance of the negative insulation resistor to ground R− is the negative insulation resistance to ground Rₑ₋. R0 represents a neutral-wire insulation resistor to ground, and a resistance of the neutral-wire insulation resistor to ground R0 is the neutral-wire insulation resistance to ground Rₑ₀.

In an embodiment, the resistance units include a switch and at least one resistance subunit. The resistance subunit includes at least one resistor, the at least one resistor is connected in series or in parallel, and the number of target output wires is the same as that of resistance subunits. The target output wire includes at least one of the positive bus, the negative bus bar, and the neutral wire, that is, the maximum number of target output wires is 3. Thus, the number of resistance subunits may be 3 or greater. A structure of the resistance unit is described in detail as follows.

In an embodiment, the target output wire includes one of the positive bus A, the negative bus C and the neutral wire B.

The resistance unit 23 includes a first switch K1 and a first resistance subunit, where the first resistance subunit includes at least one first resistor and the at least one first resistor is connected in series or in parallel.

A first terminal of the first resistance subunit is electrically connected to the target output wire, and a second terminal of the first resistance subunit is electrically connected to a first terminal of the first switch K1.

A second terminal of the first switch K1 is electrically connected to a ground terminal.

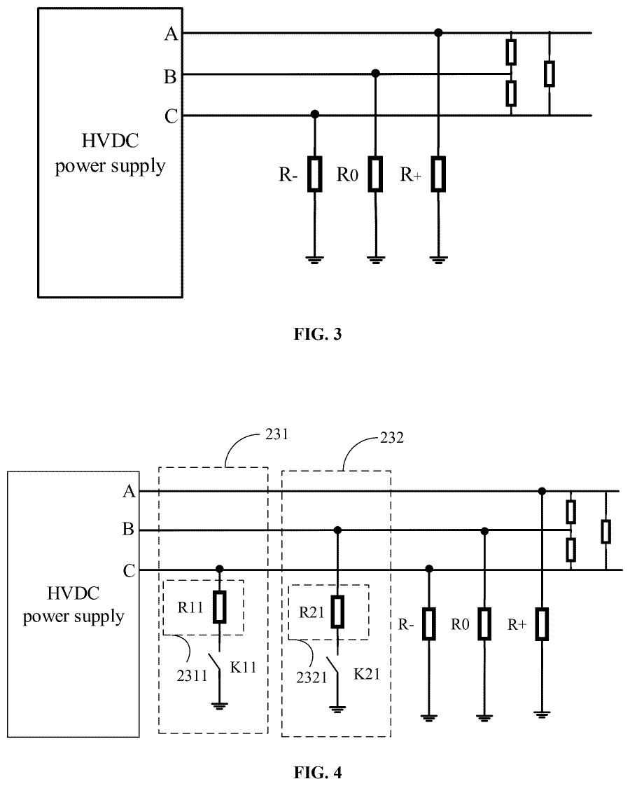

Reference is made to FIG. 4, which is a schematic diagram of a circuit of a resistance unit according to an embodiment of the present disclosure. The device for insulation detection includes two resistance units: a resistance unit 231 and a resistance unit 232. The target output wire corresponding to the resistance unit 231 is the negative bus C, and the target output wire corresponding to the resistance unit 232 is the neutral wire B.

The resistance unit 231 includes a first switch K11 and a first resistance subunit 2311. The first resistance subunit 2311 includes a first resistor R11, where a first terminal of the first resistor R11 is electrically connected to the negative bus C and a second terminal of the first resistor R11 is electrically connected to a first terminal of the first switch K11. A second terminal of the first switch K11 is grounded.

The resistance unit 232 includes a first switch K21 and a first resistance subunit 2321. The first resistance subunit 2321 includes a first resistor R21, where a first terminal of the first resistor R21 is electrically connected to the neutral wire B and a second terminal of the first resistor R21 is electrically connected to a first terminal of the first switch K21. A second terminal of the first switch K21 is grounded.

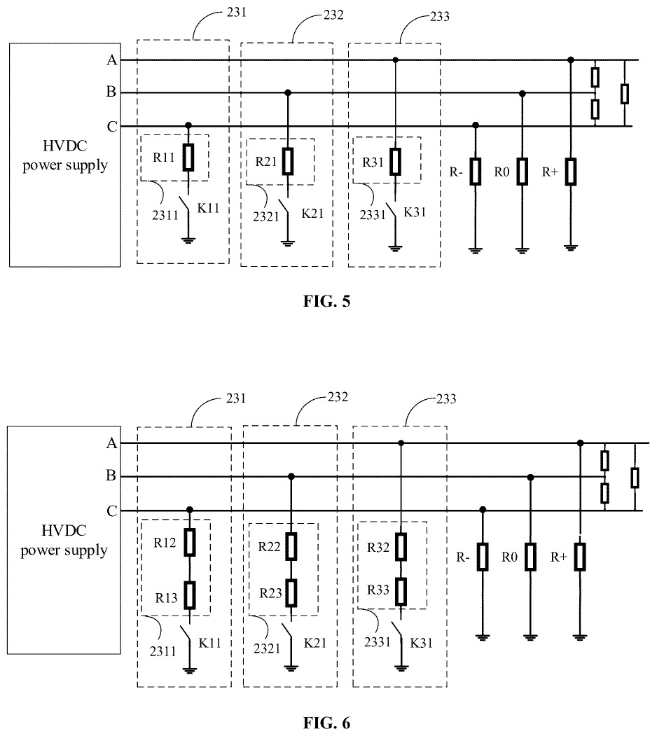

For example, as shown in FIG. 5, which is a schematic diagram of a circuit of another resistance unit according to an embodiment of the present disclosure. The device for insulation detection includes three resistance units: the resistance unit 231, the resistance unit 232, and a resistance unit 233. The target output wire corresponding to the resistance unit 231 is the negative bus C, the target output wire corresponding to the resistance unit 232 is the neutral wire B, and the target output wire corresponding to the resistance unit 233 is the positive bus A.

The resistance unit 231 includes the first switch K11 and the first resistance subunit 2311. The first resistance subunit 2311 includes the first resistor R11, where the first terminal of the first resistor R11 is electrically connected to the negative bus C and the second terminal of the first resistor R11 is electrically connected to the first terminal of the first switch K11. The second terminal of the first switch K11 is grounded.

The resistance unit 232 includes the first switch K21 and the resistance subunit 2321. The first resistance subunit 2321 includes the first resistor R21, where the first terminal of the first resistor R21 is electrically connected to the neutral wire B and the second terminal of the first resistor R21 is electrically connected to the first terminal of the first switch K21. The second terminal of the first switch K21 is grounded.

The resistance unit 233 includes a first switch K31 and a first resistance subunit 2331. The first resistance subunit 2331 includes a first resistor R31, where a first terminal of the first resistor R31 is electrically connected to the positive bus A and a second terminal of the first resistor R31 is electrically connected to a first terminal of the first switch K31. A second terminal of the first switch K31 is grounded.

For example, as shown in FIG. 6, which is a schematic diagram of a circuit of another resistance unit according to an embodiment of the present disclosure. The device for insulation detection includes three resistance units: the resistance unit 231, the resistance unit 232, and the resistance unit 233. The target output wire corresponding to the resistance unit 231 is the negative bus C, the target output wire corresponding to the resistance unit 232 is the neutral wire B, and the target output wire corresponding to the resistance unit 233 is the positive bus A.

The resistance unit 231 includes the first switch K11 and the first resistance subunit 2311. The first resistance subunit 2311 includes a first resistor R12 and a first resistor R13 that are connected in series, where a first terminal of the first resistor R12 is electrically connected to the negative bus C, a second terminal of the first resistor R12 is electrically connected to a first terminal of the first resistor R13, and a second terminal of the first resistor R13 is electrically connected to the first terminal of the first switch K11. The second terminal of the first switch K11 is grounded.

The resistance unit 232 includes the first switch K21 and the first resistance subunit 2321. The first resistance subunit 2321 includes a first resistor R22 and a first resistor R23 that are connected in series, where a first terminal of the first resistor R22 is electrically connected to the neutral wire B, a second terminal of the first resistor R22 is electrically connected to a first terminal of the first resistor R23, and a second terminal of the first resistor R23 is electrically connected to the first terminal of the first switch K21. The second terminal of the first switch K21 is grounded.

The resistance unit 233 includes the first switch K31 and the first resistance subunit 2331. The first resistance subunit 2331 includes a first resistor R32 and a first resistor R33 that are connected in series, where a first terminal of the first resistor R32 is electrically connected to the positive bus A, a second terminal of the first resistor R32 is electrically connected to a first terminal of the first resistor R33, and a second terminal of the first resistor R33 is electrically connected to the first terminal of the first switch K31. The second terminal of the first switch K31 is grounded.

For example, as shown in FIG. 7, which is a schematic diagram of a circuit of another resistance unit according to an embodiment of the present disclosure. The device for insulation detection includes three resistance units: the resistance unit 231, the resistance unit 232, and the resistance unit 233. The target output wire corresponding to the resistance unit 231 is the negative bus C, the target output wire corresponding to the resistance unit 232 is the neutral wire B, and the target output wire corresponding to the resistance unit 233 is the positive bus A.

The resistance unit 231 includes the first switch K11 and the first resistance subunit 2311. The first resistance subunit 2311 includes a first resistor R14 and a first resistor R15 that are connected in parallel, where both a first terminal of the first resistor R14 and a first terminal of the first resistor R15 are electrically connected to the negative bus C, and both a second terminal of the first resistor R14 and a second terminal of the first resistor R15 are electrically connected to the first terminal of the first switch K11. The second terminal of the first switch K11 is grounded.

The resistance unit 232 includes the first switch K21 and the first resistance subunit 2321. The first resistance subunit 2321 includes a first resistor R24 and a first resistor R25 that are connected in parallel, where both a first terminal of the first resistor R24 and a first terminal of the first resistor R25 are electrically connected to the neutral wire B, and both a second terminal of the first resistor R24 and a second terminal of the first resistor R25 are electrically connected to the first terminal of the first switch K21. The second terminal of the first switch K21 is grounded.

The resistance unit 233 includes the first switch K31 and a first resistance subunit 2331. The first resistance subunit 2331 includes a first resistor R34 and a first resistor R35 that are connected in parallel, where both a first terminal of the first resistor R34 and a first terminal of the first resistor R35 is electrically connected to the positive bus A, and both a second terminal of the first resistor R34 and a second terminal of the first resistor R35 are electrically connected to the first terminal of the first switch K31. The second terminal of the first switch K31 is grounded.

It should be noted that the number of resistance units and the number and connection mode of first resistors in the first resistance subunit may vary with actual application requirements. In addition, the connection mode of first resistors in a first resistance subunit may include both series and parallel, in addition to series only or parallel only described above as an example, which is not limited in embodiments of the present disclosure.

The above embodiments only give examples in which two or three resistance units are included. Furthermore, more than three resistance units may be included, which is not described as an example herein.

In an embodiment of the present disclosure, in a case that the device for insulation detection includes two or three resistance units and each of the resistance units includes one first resistance subunit, the target output wire corresponding to each resistance unit includes one of the positive bus A, the negative bus C, and the neutral wire B, and the target output wires corresponding to each resistance unit are different.

For the device for insulation detection including two resistance units, referring to FIG. 4, the target output wire corresponding to the resistance unit 231 is the negative bus C, however, the target output wire corresponding to the resistance unit 231 may also be the neutral wire B or the positive bus A.

For the device for insulation detection including three resistance units, referring to FIG. 5, the target output wire corresponding to the resistance unit 231 is the negative bus C, the target output wire corresponding to the resistance unit 232 is the neutral wire B, and the target output wire corresponding to the resistance unit 233 is the positive bus A.

In an embodiment, for the resistance unit including two resistance subunits, the target output wire includes a first target output wire and a second target output wire, where the first target output wire and the second target output wire are any two of the positive bus, the negative bus and the neutral wire and the first target output wire is different from the second target output wire.

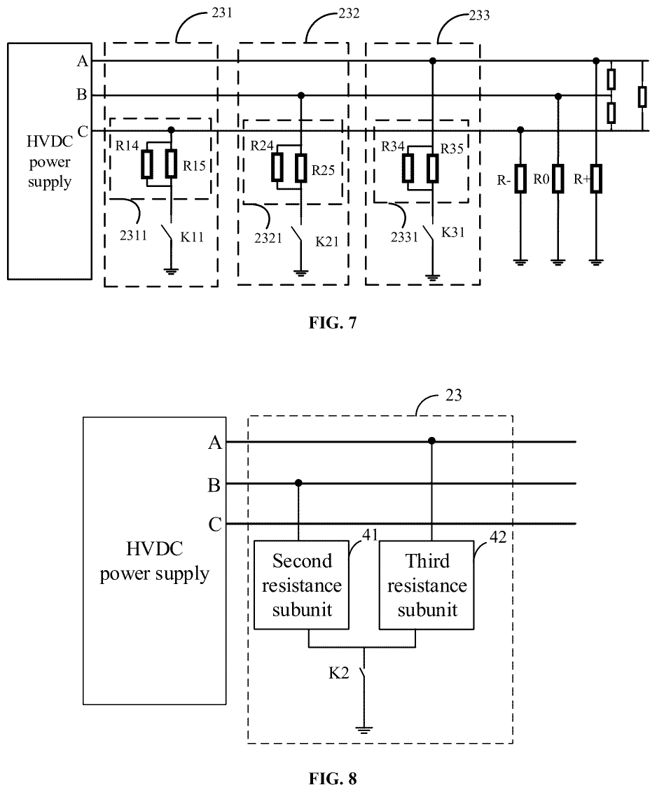

Referring to FIG. 8, the resistance unit 23 includes a second switch K2, a second resistance subunit 41 and a third resistance subunit 42. The second resistance subunit 41 includes at least one second resistor, and the third resistance subunit 42 includes at least one third resistor.

A first terminal of the second resistance subunit 41 is electrically connected to the first target output wire, and a second terminal of the second resistance subunit 41 is electrically connected to a first terminal of the second switch K2.

A first terminal of the third resistance subunit 42 is electrically connected to the second target output wire, and a second terminal of the third resistance subunit 42 is electrically connected to the first terminal of the second switch K2.

A second terminal of the second switch K2 is electrically connected to a ground terminal.

In the embodiment according to the present disclosure, the second resistance subunit 41 includes at least one second resistor. In a case that only one second resistor is included, the first terminal of the second resistor is the first terminal of the second resistance subunit 41, and the second terminal of the second resistor is the second terminal of the second resistance subunit 41. In a case that at least two second resistors are included, the at least two second resistors may be connected in series, in parallel, or both in series and in parallel, which is not limited in the embodiment of the present disclosure.

Regarding to the structure of the third resistance subunit 42, reference can be made to the structure of the second resistance subunit 41 mentioned above, which will not be repeated herein.

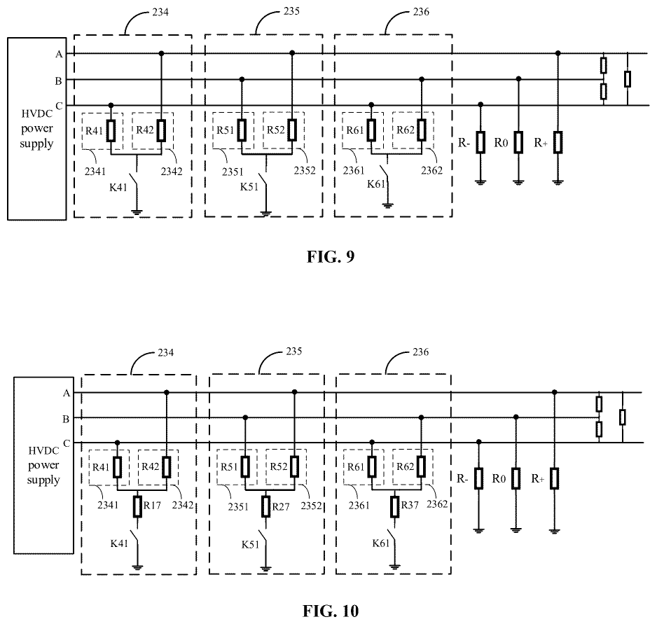

For example, as shown in FIG. 9, which is a schematic diagram of a circuit of another resistance unit according to an embodiment of the present disclosure. The device for insulation detection includes three resistance units: a resistance unit 234, a resistance unit 235, and a resistance unit 236. The target output wires corresponding to the resistance unit 234 are the negative bus C and the positive bus A, the target output wires corresponding to the resistance unit 235 are the neutral wire B and the positive bus A, and the target output wires corresponding to the resistance unit 236 are the negative bus C and the neutral wire B.

The resistance unit 234 includes a second switch K41, a second resistance subunit 2341, and a third resistance subunit 2342. The second resistance subunit 2341 includes a second resistor R41, where a first terminal of the second resistor R41 is electrically connected to the negative bus C and a second terminal of the second resistor R41 is electrically connected to a first terminal of the second switch K41. The third resistance subunit 2342 includes a second resistor R42, where a first terminal of the second resistor R42 is electrically connected to the positive bus A and a second terminal of the second resistor R42 is electrically connected to the first terminal of the second switch K41. A second terminal of the second switch K41 is grounded.

The resistance unit 235 includes a second switch K51, a second resistance subunit 2351 and a third resistance subunit 2352. The second resistance subunit 2351 includes a second resistor R51, where a first terminal of the second resistor R51 is electrically connected to the neutral wire B, a second terminal of the second resistor R51 is electrically connected to a first terminal of the second switch K51. The third resistance subunit 2352 includes a second resistor R52, where a first terminal of the second resistor R52 is electrically connected to the positive bus A and a second terminal of the second resistor R52 is electrically connected to the first terminal of the second switch K51. A second terminal of the first switch K51 is grounded.

The resistance unit 236 includes a second switch K61, a second resistance subunit 2361, and a third resistance subunit 2362. The second resistance subunit 2361 includes a second resistor R61, where a first terminal of the second resistor R61 is electrically connected to the negative bus C and a second terminal of the second resistor R61 is electrically connected to a first terminal of the second switch K61. The third resistance subunit 2362 includes a second resistor R62, where a first terminal of the second resistor R62 is electrically connected to the neutral wire B and a second terminal of the second resistor R62 is electrically connected to the first terminal of the second switch K61. A second terminal of the second switch K61 is grounded.

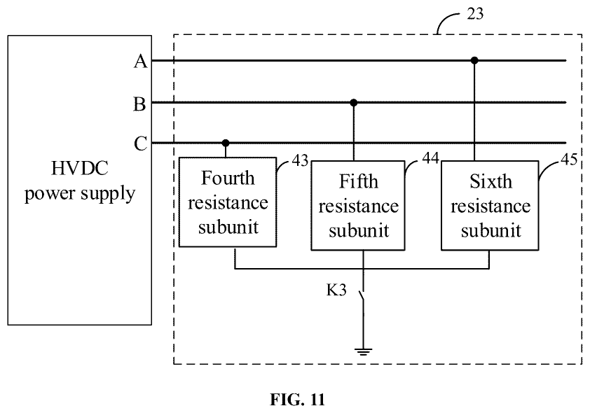

In another embodiment, a resistance unit includes a seventh resistor R17, R27, or R37. As shown in FIG. 10, the device for insulation detection includes three resistance units: the resistance unit 234, the resistance unit 235, and the resistance unit 236. The target output wires corresponding to the resistance unit 234 are the negative bus C and the positive bus A, the target output wires corresponding to the resistance unit 235 are the neutral wire B and the positive bus A, and the target output wires corresponding to the resistance unit 236 are the negative bus C and the neutral wire B.

The resistance unit 234 includes the second switch K41, the second resistance subunit 2341, the third resistance subunit 2342, and the seventh resistor R17. The second resistance subunit 2341 includes the second resistor R41, where the first terminal of the second resistor R41 is electrically connected to the negative bus C and the second terminal of the second resistor R41 is electrically connected to a first terminal of the seventh resistor R17. The third resistance subunit 2342 includes the second resistor R42, where the first terminal of the second resistor R42 is electrically connected to the positive bus A and the second terminal of the second resistor R42 is electrically connected to the first terminal of the seventh resistor R17. A second terminal of the seventh resistor R17 is electrically connected to the first terminal of the second switch K41, and the second terminal of the second switch K41 is grounded.

The resistance unit 235 includes the second switch K51, the second resistance subunit 2351, the third resistance subunit 2352, and a seventh resistor R27. The second resistance subunit 2351 includes the second resistor R51, where the first terminal of the second resistor R51 is electrically connected to the neutral wire B and the second terminal of the second resistor R51 is electrically connected to a first terminal of the seventh resistor R27. The third resistance subunit 2352 includes the second resistor R52, where the first terminal of the second resistor R52 is electrically connected to the positive bus A and the second terminal of the second resistor R52 is electrically connected to the first terminal of the seventh resistor R27. A second terminal of the seventh resistor R27 is electrically connected to the first terminal of the second switch K51, and the second terminal of the second switch K51 is grounded.

The resistance unit 236 includes the second switch K61, the second resistance subunit 2361, the third resistance subunit 2362, and a seventh resistor R37. The second resistance subunit 2361 includes the second resistor R61, where the first terminal of the second resistor R61 is electrically connected to the negative bus C and the second terminal of the second resistor R61 is electrically connected to a first terminal of the seventh resistor R37. The third resistance subunit 2362 includes the second resistor R62, where the first terminal of the second resistor R62 is electrically connected to the neutral wire B and the second terminal of the second resistor R62 is electrically connected to the first terminal of the seventh resistor R37. A second terminal of the seventh resistor R37 is electrically connected to the first terminal of the second switch K61, and the second terminal of the second switch K61 is grounded.

It should be noted that the numbers of resistance units, the number and connection mode of second resistors in a second resistance subunit, and the number and connection mode of third resistors in a third resistance subunit may vary with actual application requirements. In addition, the connection mode of second resistors in a second resistance subunit and the connection mode of third resistors in a third resistance subunit may include series only, parallel only, and both series and parallel, which is not limited in the embodiments of the present disclosure.

The above embodiments only give examples in which three resistance units are included. Of course, two resistance units or more than three resistance units may also be included, which are not described as an example herein.

In an embodiment, the target output wire includes the positive bus A, the negative bus C and the neutral wire B.

As shown in FIG. 11, the resistance unit 23 includes a third switch K3, a fourth resistance subunit 43, a fifth resistance subunit 44 and a sixth resistance subunit 45. The fourth resistance subunit 43 includes at least one fourth resistor, the fifth resistance subunit 44 includes at least one fifth resistor, and the sixth resistance subunit 45 includes at least one sixth resistor.

A first terminal of the fourth resistance subunit 43 is electrically connected to the negative bus C of the target output wire, and a second terminal of the fourth resistance subunit 43 is electrically connected to a first terminal of the third switch K3.

A first terminal of the fifth resistance subunit 44 is electrically connected to the neutral wire B of the target output wire, and a second terminal of the fifth resistance subunit 44 is electrically connected to the first terminal of the third switch K3.

A first terminal of the sixth resistance subunit 45 is electrically connected to the positive bus A of the target output wire, and a second terminal of the sixth resistance subunit 45 is electrically connected to the first terminal of the third switch K3.

A second terminal of the third switch K3 is electrically connected to a ground terminal.

In the embodiment according to the present disclosure, the fourth resistance subunit 43 includes at least one fourth resistor. In a case that only one fourth resistor is included, the first terminal of the fourth resistor is the first terminal of the fourth resistance subunit 43, the second terminal of the fourth resistor is the second terminal of the fourth resistance subunit 43. In a case that at least two fourth resistors are included, the at least two fourth resistors may be connected in series only, in parallel only, or both in series and in parallel, which is not limited in the embodiment of the present disclosure.

Regarding to structures of the fifth resistance subunit 44 and the sixth resistance subunit 45, reference can be made to the structure of the fourth resistance subunit 43 mentioned above, which will not be repeated herein.

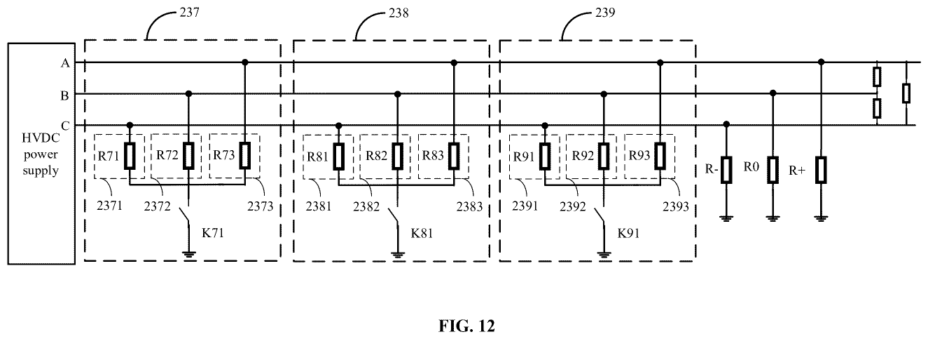

For example, as shown in FIG. 12, which is a schematic diagram of a circuit of another resistance unit according to an embodiment of the present disclosure. Referring to FIG. 12, the device for insulation detection includes three resistance units: a resistance unit 237, a resistance unit 238, and a resistance unit 239. The target output wires of each of the three resistance units are the negative bus C, the neutral wire B and the positive bus A.

The resistance unit 237 includes a fourth resistance subunit 2371, a fifth resistance subunit 2372, a sixth resistance subunit 2373 and a third switch K71. The fourth resistance subunit 2371 includes a fourth resistor R71, the fifth resistance subunit 2372 includes a fourth resistor R72, and the sixth resistance subunit 2373 includes a fourth resistor R73.

A first terminal of the fourth resistor R71 is electrically connected to the negative bus C, a first terminal of the fourth resistor R72 is electrically connected to the neutral wire B, and a first terminal of the fourth resistor R73 is electrically connected to the positive bus A. A second terminal of the fourth resistor R71, a second terminal of the fourth resistor R72 and a second terminal of the fourth resistor R73 are all electrically connected to a first terminal of the third switch K71, and a second terminal of the third switch K71 is grounded.

The resistance unit 238 includes a fourth resistance subunit 2381, a fifth resistance subunit 2382, a sixth resistance subunit 2383 and a third switch K81. The fourth resistance subunit 2381 includes a fourth resistor R81, the fifth resistance subunit 2382 includes a fourth resistor R82, and the sixth resistance subunit 2383 includes a fourth resistor R83.

A first terminal of the fourth resistor R81 is electrically connected to the negative bus C, a first terminal of the fourth resistor R82 is electrically connected to the neutral wire B, a first terminal of the fourth resistor R83 is electrically connected to the positive bus A. A second terminal of the fourth resistor R81, a second terminal of the fourth resistor R82 and a second terminal of the fourth resistor R83 are all electrically connected to a first terminal of the third switch K81, and a second terminal of the third switch K81 is grounded.

The resistance unit 239 includes a fourth resistance subunit 2391, a fifth resistance subunit 2392, a sixth resistance subunit 2393 and a third switch K91. The fourth resistance subunit 2391 includes a fourth resistor R91, the fifth resistance subunit 2392 includes fourth resistor R92, and the sixth resistance subunit 2393 includes the fourth resistor R93.

A first terminal of the fourth resistor R91 is electrically connected to the negative bus C, a first terminal of the fourth resistor R92 is electrically connected to the neutral wire B, a first terminal of the fourth resistor R93 is electrically connected to the positive bus A. A second terminal of the fourth resistor R91, a second terminal of the fourth resistor R92 and a second terminal of the fourth resistor R93 are all electrically connected to a first terminal of the third switch K91, and a second terminal of the third switch K91 is grounded.

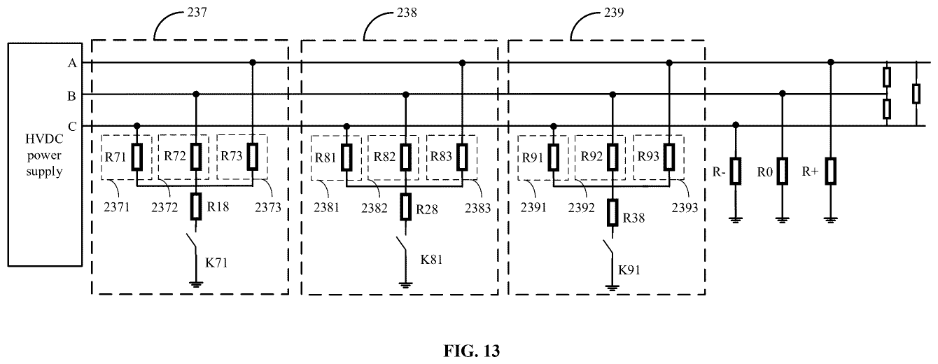

In another embodiment, as shown in FIG. 13, each of the resistance units 237, 238, and 239 further includes an eighth resistor.

The device for insulation detection includes three resistance units: the resistance unit 237, the resistance unit 238, and the resistance unit 239. The target output wires of each of the three resistance units are the negative bus C, the neutral wire B and the positive bus A.

The resistance unit 237 includes the fourth resistance subunit 2371, the fifth resistance subunit 2372, the sixth resistance subunit 2373, the third switch K71 and an eighth resistor R18. The fourth resistance subunit 2371 includes the fourth resistor R71, the fifth resistance subunit 2372 includes the fourth resistor R72, and the sixth resistance subunit 2373 includes the fourth resistor R73.

The first terminal of the fourth resistor R71 is electrically connected to the negative bus C, the first terminal of the fourth resistor R72 is electrically connected to the neutral wire B, and the first terminal of the fourth resistor R73 is electrically connected to the positive bus A. The second terminal of the fourth resistor R71, the second terminal of the fourth resistor R72, and the second terminal of the fourth resistor R73 are all electrically connected to a first terminal of the eighth resistor R18, a second terminal of the eighth resistor R18 is electrically connected to the first terminal of the third switch K71, and the second terminal of the third switch K71 is grounded.

The resistance unit 238 includes the fourth resistance subunit 2381, the fifth resistance subunit 2382, the sixth resistance subunit 2383, a third switch K81 and an eighth resistor R28. The fourth resistance subunit 2381 includes the fourth resistor R81, the fifth resistance subunit 2382 includes the fourth resistor R82, and the sixth resistance subunit 2383 includes the fourth resistor R83.

The first terminal of the fourth resistor R81 is electrically connected to the negative bus C, the first terminal of the fourth resistor R82 is electrically connected to the neutral wire B, and the first terminal of the fourth resistor R83 is electrically connected to the positive bus A. The second terminal of the fourth resistor R81, the second terminal of the fourth resistor R82 and the second terminal of the fourth resistor R83 are all electrically connected to a first terminal of the eighth resistor R28, a second terminal of the eighth resistor R28 is electrically connected to the first terminal of the third switch K81, and the second terminal of the third switch K81 is grounded.

The resistance unit 239 includes the fourth resistance subunit 2391, the fifth resistance subunit 2392, the sixth resistance subunit 2393, the third switch K91 and an eighth resistor R38. The fourth resistance subunit 2391 includes the fourth resistor R91, the fifth resistance subunit 2392 includes the fourth resistor R92, and the sixth resistance subunit 2393 includes the fourth resistor R93.

The first terminal of the fourth resistor R91 is electrically connected to the negative bus C, the first terminal of the fourth resistor R92 is electrically connected to the neutral wire B, and the first terminal of the fourth resistor R93 is electrically connected to the positive bus A. The second terminal of the fourth resistor R91, the second terminal of the fourth resistor R92 and the second terminal of the fourth resistor R93 are all electrically connected to a first terminal of the eighth resistor R38, a second terminal of the eighth resistor R38 is electrically connected to the first terminal of the third switch K91, and the second terminal of the third switch K91 is grounded.

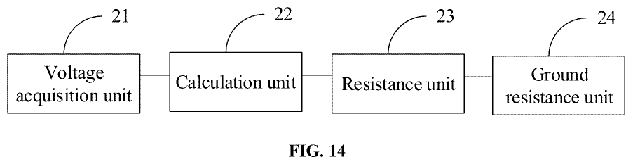

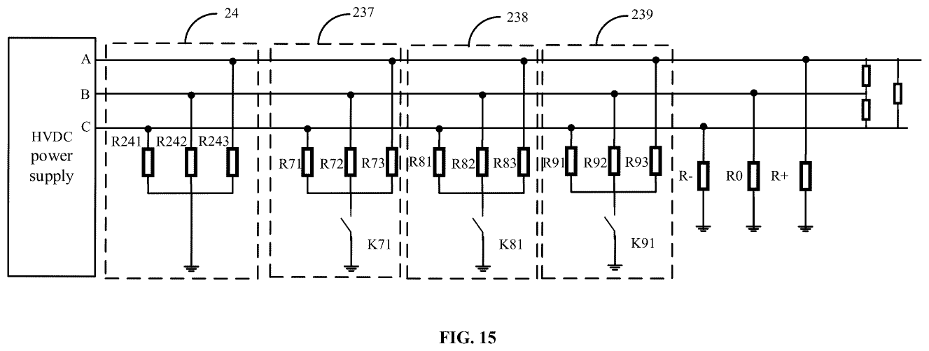

In an embodiment, as shown in FIG. 14, which is a schematic structural diagram of another device for insulation detection according to an embodiment of the present disclosure. The device for insulation detection further includes a ground resistance unit 24, and the ground resistance unit 24 includes at least one ground resistor.

One terminal of the ground resistor is electrically connected to one output wire of the three-wire HVDC system, and the other terminal of the ground resistor is electrically connected to the ground terminal.

In the embodiment according to the present disclosure, the output wire includes any one of the positive bus A, the neutral wire B and the negative bus C. For example, as shown in FIG. 15, the ground resistance unit 24 includes a ground resistor R241, a ground resistor R242 and a ground resistor R243.

A first terminal of the ground resistor R241 is electrically connected to the negative bus C, and a second terminal of the ground resistor R241 is electrically connected to a ground terminal.

A first terminal of the ground resistor R242 is electrically connected to the neutral wire B, and a second terminal of the ground resistor R242 is electrically connected to the ground terminal.

A first terminal of the ground resistor R243 is electrically connected to the positive bus A, and a second terminal of the ground resistor R243 is electrically connected to the ground terminal.

It should be noted that the number of ground resistors may be adjusted according to actual application requirements.

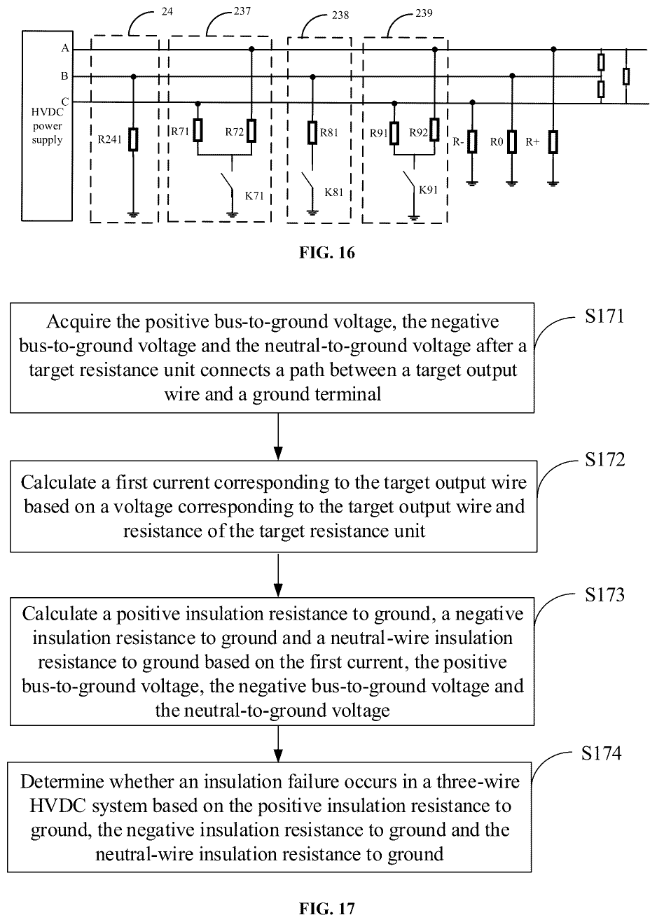

In an embodiment, target output wires within the resistance unit may be different. As shown in FIG. 16, the ground resistance unit includes the ground resistor R241. In the resistance unit 237, the second resistance subunit includes the second resistor R71 and the third resistance subunit includes the third resistor R72. The target output wire of the second resistor R71 is the negative bus C, and the target output wire of the third resistor R72 is a positive bus A. In the resistance unit 238, the first resistance subunit includes the first resistor R81, and the target output wire of the first resistor R81 is the neutral wire B. In the resistance unit 239, the second resistance subunit includes the second resistor R91 and the third resistance subunit includes the third resistor R92. The target output wire of the second resistor R91 is the negative bus C, and the target output wire of the third resistor R92 is the positive bus A.

The above describes resistance units and ground resistance units in the device for insulation detection. In an embodiment, the voltage acquisition unit 21 acquires the positive bus-to-ground voltage U+, the negative bus-to-ground voltage U− and the neutral-to-ground voltage U0 after the target resistance unit connects a path between the target output wire and the ground terminal. The calculation unit 22 calculates the first current I1 corresponding to the target output wire based on the voltage corresponding to target output wire and the resistance of the target resistance unit; and calculates the positive insulation resistance to ground Rₑ₊, the negative insulation resistance to ground Rₑ₋ and the neutral-wire insulation resistance to ground Rₑ₀ based on the first current I1, the positive bus-to-ground voltage U+, the negative bus-to-ground voltage U− and the neutral-to-ground voltage U0.

In an embodiment, the calculation unit 22 calculates the first quotient of the voltage corresponding to the target output wire and the resistance of the target resistance unit to acquire the first current; generates the first current equation, the second current equation and the third current equation based on the first current I1, a positive bus current I+, a negative bus current I− and a neutral wire current I0, where the first current equation, the second current equation and the third current equation are generated based on different target resistance units.

Specifically, the positive bus current I+ represents a quotient of the voltage of the positive bus A and positive insulation resistance to ground, the negative bus current I− represents the quotient of the voltage of the negative bus C and negative insulation resistance to ground, and the neutral wire current I0 represents the quotient of the voltage of the neutral wire B and neutral-wire insulation resistance to ground.

The positive insulation resistance to ground Rₑ₊, negative insulation resistance to ground Rₑ₋ and neutral-wire insulation resistance to ground Rₑ₀ is calculated based on the first current equation, the second current equation and the third current equation.

For example, referring to the circuit in FIG. 5, if the first switch K11 is closed, the target resistance unit is the resistance unit 231 and the target output wire is the negative bus C; and the voltage acquisition unit 21 acquires a positive bus-to-ground voltage U1+, a negative bus-to-ground voltage U1− and a neutral wire-to-ground voltage U10 at this moment.

The calculation unit 22 is configured to calculate the first quotient of the negative bus-to-ground voltage U1− and the resistance of the first resistor R11 to acquire t first current I11, that is

$${I}_{11} = \frac{{U}_{1 -}}{R 11} .$$

Applying Kirchhoff's current law, the first current equation, that is

$$\frac{{U}_{1 -}}{R 11} + \frac{{U}_{1 -}}{R -} + \frac{{U}_{10}}{R 0} + \frac{{U}_{1 +}}{R +} = 0 ,$$

is generated based on the first current I11, the positive bus current I+, the negative bus current I− and the neutral wire current I0.

If the first switch K21 is closed, the target resistance unit is the resistance unit 232 and the target output wire is the neutral wire B; and the voltage acquisition unit 21 acquires a positive bus-to-ground voltage U2+, a negative bus-to-ground voltage U2− and a neutral wire-to-ground voltage U20 at this moment.

The calculation unit 22 is configured to calculate the first quotient of the neutral wire-to-ground voltage U20 and the resistance of the first resistor R21 to acquire a first current I12, that is,

$${I}_{12} = \frac{{U}_{20}}{R 21} .$$

Applying Kirchhoff's current law, the second current equation, that is

$$\frac{{U}_{20}}{R 21} + \frac{{U}_{2 -}}{R -} + \frac{{U}_{20}}{R 0} + \frac{{U}_{2 +}}{R +} = 0 ,$$

is generated based on the first I12, the positive bus current I+, the negative bus current I− and the neutral wire current I0.

If the first switch K31 is closed, the target resistance unit is the resistance unit 233 and the target output wire is the positive bus A; and the voltage acquisition unit 21 acquires the positive bus-to-ground voltage U3+, a negative bus-to-ground voltage U3− and a neutral wire-to-ground voltage U30 at this moment.

The calculation unit 22 is configured to calculate the first quotient of the positive bus-to-ground voltage U3+ and resistance of the first resistor R31 to acquire a first current I13, that is,

$${I}_{13} = + \frac{{U}_{3 +}}{R 31} .$$

Applying Kirchhoff's current law, the third current equation, that is

$$\frac{{U}_{3 +}}{R 31} + \frac{{U}_{3 -}}{R -} + \frac{{U}_{30}}{R 0} + \frac{{U}_{3 +}}{R +} = 0 ,$$

is generated based on the first current I13, the positive bus current I+, the negative bus current I− and the neutral wire current I0.

The calculation unit 22 calculates the positive insulation resistance to ground Rₑ₊, the negative insulation resistance to ground Rₑ₋ and the neutral-wire insulation resistance to ground Rₑ₀ by combining the first current equation, the second current equation and the third current equation.

It should be noted that at least one first switch is closed each time.

In another embodiment, the voltage acquisition unit 21 acquires the positive bus-to-ground voltage U+, the negative bus-to-ground voltage U− and the neutral-to-ground voltage U0 after the target resistance unit and the ground resistance unit connects a path between the target output wire and the ground terminal. The calculation unit 22 calculates the first current I1 and a second current I2 corresponding to the target output wire based on voltages corresponding to the target output wire and resistance of the target resistance unit; and calculates the positive insulation resistance to ground Rₑ₊, the negative insulation resistance to ground Rₑ₋ and the neutral-wire insulation resistance to ground Rₑ₀ based on the first current I1, the second current I2, the positive bus-to-ground voltage U+, the negative bus-to-ground voltage U− and the neutral-to-ground voltage U0.

During implementation, the calculation unit 22 calculates the first quotient of the voltage corresponding to the target output wire and the resistance of the target resistance unit to acquire the first current I1, and calculates the second quotient of the voltage corresponding to the target output wire and the resistance of the ground resistance unit to acquire the second current I2; generates the fourth current equation, the fifth current equation and the sixth current equation based on the first current I1, the second current I2, the positive bus current I+, the negative bus current I− and the neutral wire current I0, where the fourth current equation, the fifth current equation and the sixth current equation are generated based on different target resistance units; specifically, the positive bus current I+ represents the quotient of the voltage of the positive bus A and positive insulation resistance to ground, the negative bus current I− represents the quotient of the voltage of a negative bus C and negative insulation resistance to ground, and the neutral wire current I0 represents the quotient of the voltage of the neutral wire B and neutral-wire insulation resistance to ground.

Positive insulation resistance to ground Rₑ₊, negative insulation resistance to ground Rₑ₋ and neutral-wire insulation resistance to ground Rₑ₀ is calculated based on the fourth current equation, the fifth current equation and the sixth current equation.

For example, as shown in FIG. 15, which is a schematic diagram of a circuit of a device for insulation detection according to an embodiment of the present disclosure.

If the third switch K71 is closed, the target resistance unit includes the ground resistance unit 24 and the resistance unit 237, and target output wires include the negative bus C, the neutral wire B and the positive bus A; and the voltage acquisition unit 21 acquires a positive bus-to-ground voltage U4+, a negative bus-to-ground voltage U4− and a neutral wire-to-ground voltage U40 at this moment.

The calculation unit 22 is configured to calculate the quotient of the negative bus-to-ground voltage U4− and the fourth resistor R71, the quotient of the neutral wire-to-ground voltage U40 and the fourth resistor R72 and the quotient of the positive bus-to-ground voltage U4+ and the fourth resistor R73 to acquire a first current I14, that is

$${I}_{14} = \frac{{U}_{4 -}}{R 71} + \frac{{U}_{40}}{R 72} + \frac{{U}_{4 +}}{R 72} + \frac{{U}_{4 +}}{R 73} .$$

The calculation unit 22 is configured to calculate the quotient of the negative bus-to-ground voltage U4− and the ground resistor R241, the quotient of the neutral wire-to-ground voltage U40 and the ground resistor R242 and the quotient of the positive bus-to-ground voltage U4+ and the ground resistor R243 to acquire a second current I21, that is

$${I}_{21} = \frac{{U}_{4 -}}{R 241} + \frac{{U}_{40}}{R 242} + \frac{{U}_{4 +}}{R 243} .$$

Applying Kirchhoff's current law, based on the first current I14, the second current I21, the positive bus current I+, the negative bus current I− and the neutral wire current I0, the fourth current equation is generated as follows:

$$\frac{{U}_{4 -}}{R 241} + \frac{{U}_{40}}{R 242} + \frac{{U}_{4 +}}{R 243} + \frac{{U}_{4 -}}{R 71} + \frac{{U}_{40}}{R 72} + \frac{{U}_{4 +}}{R 73} + \frac{{U}_{4 -}}{R -} + \frac{{U}_{40}}{R 0} + \frac{{U}_{4 +}}{R +} = 0$$

If the third switch K81 is closed, the target resistance unit includes the ground resistance unit 24 and the resistance unit 238, and target output wires include the negative bus C, the neutral wire B and the positive bus A; and the voltage acquisition unit 21 acquires a positive bus-to-ground voltage U5+, a negative bus-to-ground voltage U5− and a neutral wire-to-ground voltage U50 at this moment.

The calculation unit 22 is configured to calculate the quotient of the negative bus-to-ground voltage U5− and the fourth resistor R81, the quotient of the neutral wire-to-ground voltage U50 and the fourth resistor R82 and the quotient of the positive bus-to-ground voltage U5+ and the fourth resistor R83 to acquire a first current I15, that is

$${I}_{15} = \frac{{U}_{5 -}}{R 81} + \frac{{U}_{50}}{R 82} + \frac{{U}_{5 +}}{R 83} .$$

The calculation unit 22 is configured to calculate the quotient of the negative bus-to-ground voltage U5− and the ground resistor R241, the quotient of the neutral wire-to-ground voltage U50 and the ground resistor R242 and the quotient of the positive bus-to-ground voltage U5+ and the ground resistor R243 to acquire a second current I22, that is

$${I}_{22} = \frac{{U}_{5 -}}{R 241} + \frac{{U}_{50}}{R 242} + \frac{{U}_{5 +}}{R 243} .$$

Applying Kirchhoff's current law, based on the first current I15, the second current I22, the positive bus current I+, the negative bus current I− and the neutral wire current I0, the fifth current equation is generated as follows:

$$\frac{{U}_{5 -}}{R 241} + \frac{{U}_{50}}{R 242} + \frac{{U}_{5 +}}{R 243} + \frac{{U}_{5 -}}{R 81} + \frac{{U}_{50}}{R 82} + \frac{{U}_{5 +}}{R 83} + \frac{{U}_{5 -}}{R -} + \frac{{U}_{50}}{R 0} + \frac{{U}_{5 +}}{R +} = 0$$

If the third switch K91 is closed, the target resistance unit includes the ground resistance unit 24 and the resistance unit 239, and target output wires include the negative bus C, the neutral wire B and the positive bus A; and the voltage acquisition unit 21 acquires a positive bus-to-ground voltage U6+, a negative bus-to-ground voltage U6− and a neutral wire-to-ground voltage U60 of the closed circuit at this moment.

The calculation unit 22 is configured to calculate the quotient of the negative bus-to-ground voltage U6− and the fourth resistor R91, the quotient of the neutral wire-to-ground voltage U60 and the fourth resistor R92 and the quotient of the positive bus-to-ground voltage U6+ and the fourth resistor R93 to acquire a first current I16, that is

$${I}_{16} = \frac{{U}_{6 -}}{R 91} + \frac{{U}_{60}}{R 92} + \frac{{U}_{6 +}}{R 93} .$$

The calculation unit 22 is configured to calculate the quotient of the negative bus-to-ground voltage U6− and the ground resistor R241, the quotient of the neutral wire-to-ground voltage U60 and the ground resistor R242 and the quotient of the positive bus-to-ground voltage U6+ and the ground resistor R243 to acquire a second current I23, that is

$${I}_{23} = \frac{{U}_{6 -}}{R 241} + \frac{{U}_{60}}{R 242} + \frac{{U}_{6 +}}{R 243} .$$

Applying Kirchhoff's current law, based on the first current I16, the second current I23, the positive bus current I+, the negative bus current I− and the neutral wire current I0, the sixth current equation is generated as follows:

$$\frac{{U}_{6 -}}{R 241} + \frac{{U}_{60}}{R 242} + \frac{{U}_{6 +}}{R 243} + \frac{{U}_{6 -}}{R 91} + \frac{{U}_{60}}{R 92} + \frac{{U}_{6 +}}{R 93} + \frac{{U}_{6 -}}{R -} + \frac{{U}_{60}}{R 0} + \frac{{U}_{6 +}}{R +} = 0$$

The calculation unit 22 calculates positive insulation resistance to ground Rₑ₊, negative insulation resistance to ground Rₑ₋ and neutral-wire insulation resistance to ground Rₑ₀ by combing the fourth current equation, the fifth current equation, and the sixth current equation. It should be noted that at least one third switch is closed each time.

It is determined that an insulation failure occurs based on the positive insulation resistance to ground Rₑ₊, the negative insulation resistance to ground Rₑ₋ and the neutral-wire insulation resistance to ground Rₑ₀. Specifically, it is determined that an insulation failure occurs in a load resistor on a target output wire in a case that any one of the positive insulation resistance to ground Rₑ₊, negative insulation resistance to ground Rₑ₋, and neutral-wire insulation resistance to ground Rₑ₀ is less than a pre-configured insulation resistance.

Based on the same inventive concept, an embodiment of the present disclosure further provides a method for insulation detection, which is applied to the device for insulation detection in any one of the above-described embodiments. Regarding to implementation of the method, reference can be made to the implementation of the device for insulation detection, which will not be repeated herein.

As shown in FIG. 17, the method for insulation detection according to an embodiment of the present disclosure specifically includes steps S171 to S174.

In step S171, the positive bus-to-ground voltage, the negative bus-to-ground voltage and the neutral-to-ground voltage are acquired after the target resistance unit connects a path between the target output wire and the ground terminal.

In step S172, the first current corresponding to the target output wire is calculated based on the voltage corresponding to the target output wire and the resistance of the target resistance unit.

In step S173, the positive insulation resistance to ground, the negative insulation resistance to ground and the neutral-wire insulation resistance to ground are calculated based on the first current, the positive bus-to-ground voltage, the negative bus-to-ground voltage and the neutral-to-ground voltage.

In step S174, it is determined whether an insulation failure occurs in the three-wire HVDC system based on the positive insulation resistance to ground, the negative insulation resistance to ground and the neutral-wire insulation resistance to ground.

In an optional embodiment, the calculating the positive insulation resistance to ground, the negative insulation resistance to ground and the neutral-wire insulation resistance to ground based on the first current, the positive bus-to-ground voltage, the negative bus-to-ground voltage and the neutral-to-ground voltage includes:
calculating the first quotient of the voltage corresponding to the target output wire and the resistance of the target resistance unit as the first current;
generating the first current equation, the second current equation and the third current equation based on the first current, the positive bus current, the negative bus current and the neutral wire current, where the first current equation, the second current equation and the third current equation are generated based on different target resistance units; and
calculating the positive insulation resistance to ground, the negative insulation resistance to ground and the neutral-wire insulation resistance to ground based on the first current equation, the second current equation and the third current equation.

In an optional embodiment, the method further includes:
calculating a second quotient of the voltage corresponding to the target output wire and the resistance of the ground resistance unit to acquire the second current corresponding to the target output wire;
generate the fourth current equation, the fifth current equation and the sixth current equation based on the first current, the second current, the positive bus current, the negative bus current and the neutral wire current; and
calculating the positive insulation resistance to ground, the negative insulation resistance to ground and the neutral-wire insulation resistance to ground based on the fourth current equation, the fifth current equation and the sixth current equation.

A device and a method for insulation detection are provided according embodiments of the present disclosure. The device for insulation detection includes the voltage acquisition unit, the calculation unit and at least two resistance units. Each of the resistance units is electrically connected to the ground terminal and the target output wire of the three-wire HVDC system. The voltage acquisition unit is configured to acquire the positive bus-to-ground voltage, the negative bus-to-ground voltage and the neutral-to-ground voltage after the target resistance unit connects a path between the target output wire and the ground terminal. The calculation unit is configured to calculate the first current corresponding to the target output wire based on the voltage corresponding to the target output wire and the resistance of the target resistance unit; calculate the positive insulation resistance to ground, the negative insulation resistance to ground and the neutral-wire insulation resistance to ground based on the first current, the positive bus-to-ground voltage, the negative bus-to-ground voltage and the neutral-to-ground voltage; and determine whether an insulation failure occurs in the three-wire HVDC system based on the positive insulation resistance to ground, the negative insulation resistance to ground and the neutral-wire insulation resistance to ground. The device for insulation detection according to the embodiments of the present disclosure can perform insulation detection on the three-wire HVDC system, thereby improving safety and reliability of the three-wire HVDC system.

Those skilled in the art should understand that the embodiments of the present disclosure may be provided as methods, systems, or computer program products. Accordingly, the present disclosure may take a form of an entirely hardware embodiment, an entirely software embodiment, or an embodiment combining software and hardware aspects. Moreover, the present disclosure may take a form of a computer program product implemented on one or more computer-readable storage media (including, but not limited to, disk storage, CD-ROM, optical storage, etc.) containing computer-readable program code.

The present disclosure is described with reference to flowcharts and/or block diagrams of the methods, devices (systems), and computer program products according to the present disclosure. It should be understood that each flow in the flowcharts and/or each block in the block diagrams, as well as combinations of flows in the flowcharts and/or blocks in block diagrams, may be implemented by computer program instructions. The computer program instructions may be provided for a processor of a general-purpose computer, a special-purpose computer, an embedded processor or other programmable data processing devices to produce a machine such that the instructions, when executed by the processor of the computer or other programmable data processing devices, causes the apparatus for implementing the functions specified in one or multiple processes of the flowcharts and/or one or multiple blocks of the block diagrams.

The computer program instructions may also be stored in a computer-readable memory capable of booting a computer or other programmable data processing devices to operate in a specific manner, such that the instructions stored in the computer-readable memory produce a manufactured article, including an instruction apparatus, that implements the functions specified in the one or multiple processes of the flowcharts and/or one or multiple blocks of the block diagrams.

These computer program instructions may also be loaded onto a computer or other programmable data processing devices, enabling execution of a series of operational steps in the computer or other programmable devices to result in computer-implemented processing. Thus, the instructions executed on the computer or other programmable devices provide the steps to implement the functions specified in one or multiple processes of the flowcharts and/or one or multiple blocks of the block diagrams.

Apparently, those skilled in the art may make various modifications and variations to the present disclosure without departing from the spirit and scope of the present disclosure. In a case that such modifications and variations to the present disclosure fall within the scope of the claims of the present disclosure and their equivalents, the present disclosure also intends to include the modifications and variations.

What is claimed is:

1. A device for insulation detection, characterized in that the device for insulation detection is applied to a three-wire High-Voltage Direct Current (HVDC) system and comprises a voltage acquisition unit, a calculation unit and at least two resistance units;
each of the at least two resistance units is electrically connected to a ground terminal and a target output wire of the three-wire HVDC system, wherein the target output wire comprises at least one of a positive bus, a negative bus and a neutral wire;
the voltage acquisition unit is configured to acquire a positive bus-to-ground voltage, a negative bus-to-ground voltage and a neutral-to-ground voltage after a target resistance unit among the at least two resistance units connects a path between the target output wire and the ground terminal; and
the calculation unit is electrically connected to the voltage acquisition unit and is configured to: calculate a first current corresponding to the target output wire based on a voltage corresponding to the target output wire and a resistance of the target resistance unit; calculate a positive insulation resistance to ground, a negative insulation resistance to ground and a neutral-wire insulation resistance to ground based on the first current, the positive bus-to-ground voltage, the negative bus-to-ground voltage and the neutral-to-ground voltage; and determine whether an insulation failure occurs in the three-wire HVDC system based on the positive insulation resistance to ground, the negative insulation resistance to ground and the neutral-wire insulation resistance to ground.

2. The device according to claim 1, characterized in that the target output wire comprises one of the positive bus, the negative bus and the neutral wire;
each of the at least two resistance units comprises a first switch and a first resistance subunit, wherein the first resistance subunit comprises at least one first resistor;
a first terminal of the first resistance subunit is electrically connected to the target output wire, and a second terminal of the first resistance subunit is electrically connected to a first terminal of the first switch; and
a second terminal of the first switch is electrically connected to the ground terminal.

3. The device according to claim 1, characterized in that the target output wire comprises a first target output wire and a second target output wire, wherein the first target output wire and the second target output wire are any two of the positive bus, the negative bus and the neutral wire, and the first target output wire is different from the second target output wire;
each of the at least two resistance units comprises a second switch, a second resistance subunit and a third resistance subunit, wherein the second resistance subunit comprises at least one second resistor, and the third resistance subunit comprises at least one third resistor;
a first terminal of the second resistance subunit is electrically connected to the first target output wire, and a second terminal of the second resistance subunit is electrically connected to a first terminal of the second switch;
a first terminal of the third resistance subunit is electrically connected to the second target output wire, and a second terminal of the third resistance subunit is electrically connected to the first terminal of the second switch; and
a second terminal of the second switch is electrically connected to the ground terminal.

4. The device according to claim 1, wherein the target output wire comprises the positive bus, the negative bus and the neutral wire;
each of the at least two resistance units comprises a third switch, a fourth resistance subunit, a fifth resistance subunit and a sixth resistance subunit, wherein the fourth resistance subunit comprises at least one fourth resistor, the fifth resistance subunit comprises at least one fifth resistor, and the sixth resistance subunit comprises at least one sixth resistor;
a first terminal of the fourth resistance subunit is electrically connected to the negative bus of the target output wire, and a second terminal of the fourth resistance subunit is electrically connected to a first terminal of the third switch;
a first terminal of the fifth resistance subunit is electrically connected to the neutral wire of the target output wire, and a second terminal of the fifth resistance subunit is electrically connected to the first terminal of the third switch;
a first terminal of the sixth resistance subunit is electrically connected to the positive bus of the target output wire, and a second terminal of the sixth resistance subunit is electrically connected to the first terminal of the third switch; and
a second terminal of the third switch is electrically connected to the ground terminal.

5. The device according to claim 1, characterized in that the device for insulation detection further comprises a ground resistance unit, wherein the ground resistance unit comprises at least one ground resistor; and
one terminal of the ground resistor is electrically connected to one output wire of the three-wire HVDC system, and the other terminal of the ground resistor is electrically connected to the ground terminal.

6. The device according to claim 5, characterized in that the calculation unit is configured to:
calculate a first quotient of the voltage corresponding to the target output wire and the resistance of the target resistance unit to acquire the first current;
generate a first current equation, a second current equation and a third current equation based on the first current, a positive bus current, a negative bus current and a neutral wire current, wherein the first current equation, the second current equation and the third current equation are generated based on different target resistance units; and
calculate the positive insulation resistance to ground, the negative insulation resistance to ground and the neutral-wire insulation resistance to ground based on the first current equation, the second current equation and the third current equation.

7. The device according to claim 6, characterized in that the calculation unit is further configured to:
calculate a second quotient of the voltage corresponding to the target output wire and a resistance of the ground resistance unit to acquire a second current corresponding to the target output wire;
generate a fourth current equation, a fifth current equation and a sixth current equation based on the first current, the second current, the positive bus current, the negative bus current and the neutral wire current; and
calculate the positive insulation resistance to ground, the negative insulation resistance to ground and the neutral-wire insulation resistance to ground based on the fourth current equation, the fifth current equation and the sixth current equation.

8. A method for insulation detection, characterized in that the method for insulation detection is applied to the device for insulation detection according to claim 1 and comprises:
acquiring the positive bus-to-ground voltage, the negative bus-to-ground voltage and the neutral-to-ground voltage after the target resistance unit connects the path between the target output wire and the ground terminal;
calculating the first current corresponding to the target output wire based on the voltage corresponding to the target output wire and the resistance of the target resistance unit;
calculating the positive insulation resistance to ground, the negative insulation resistance to ground and the neutral-wire insulation resistance to ground based on the first current, the positive bus-to-ground voltage, the negative bus-to-ground voltage and the neutral-to-ground voltage; and
determining whether the insulation failure occurs in the three-wire HVDC system based on the positive insulation resistance to ground, the negative insulation resistance to ground and the neutral-wire insulation resistance to ground.

9. The method according to claim 8, characterized in that the calculating the positive insulation resistance to ground, the negative insulation resistance to ground and the neutral-wire insulation resistance to ground based on the first current, the positive bus-to-ground voltage, the negative bus-to-ground voltage and the neutral-to-ground voltage comprises:
calculating a first quotient of the voltage corresponding to the target output wire and the resistance of the target resistance unit as the first current;
generating a first current equation, a second current equation and a third current equation based on the first current, a positive bus current, a negative bus current and a neutral wire current, wherein the first current equation, the second current equation and the third current equation are generated based on different target resistance units; and
calculating the positive insulation resistance to ground, the negative insulation resistance to ground and the neutral-wire insulation resistance to ground based on the first current equation, the second current equation and the third current equation.

10. The method according to claim 9, characterized in that the method further comprises:
calculating a second quotient of the voltage corresponding to the target output wire and a resistance of a ground resistance unit to acquire a second current corresponding to the target output wire;
generating a fourth current equation, a fifth current equation and a sixth current equation based on the first current, the second current, the positive bus current, the negative bus current and the neutral wire current; and
calculating the positive insulation resistance to ground, the negative insulation resistance to ground and the neutral-wire insulation resistance to ground based on the fourth current equation, the fifth current equation and the sixth current equation,
wherein the ground resistance unit comprises at least one ground resistor; and
one terminal of the ground resistor is electrically connected to one output wire of the three-wire HVDC system, and the other terminal of the ground resistor is electrically connected to the ground terminal.
